(19) United States
(12) Patent Application Publication
(10) Pub. No.: US 2011/0298022 A1
(43) Pub. Date: Dec. 8, 2011

(54) MANUFACTURING METHOD FOR SOLID-STATE IMAGE PICKUP DEVICE, SOLID-STATE IMAGE PICKUP DEVICE AND IMAGE PICKUP APPARATUS

(75) Inventors: SANGHOOM HA, Kanagawa (JP); HIROAKI ISHIWATA, Tokyo (JP)

(73) Assignee: SONY CORPORATION, Tokyo (JP)

(21) Appl. No.: 13/116,477

(22) Filed: May 26, 2011

(30) Foreign Application Priority Data
Jun. 2, 2010 (JP) 2010-127323

(51) Int. Cl. H01L 31/0224

(52) U.S. Cl. 257/291; 438/73; 257/E31.124; 257/443

(57) ABSTRACT

A solid-state image pickup device and method for manufacturing the same. The solid-state image pickup device includes a substrate, a first charge accumulation region formed within the substrate, a first impurity region formed within the substrate and located above the charge accumulation region, and a gate electrode disposed on a surface of the substrate which is closer to the first impurity region. Further, a portion of the first impurity region and the charge accumulation region extend underneath a portion of the gate electrode, and edges of the charge accumulation region and first impurity region which lie underneath the gate electrode are in registry with each other.

The present application claims priority to Japanese Patent Application JP 2010-127323 filed in the Japan Patent Office on Jun. 2, 2010, the entirety of which is hereby incorporated by reference to the extent permitted by law.

### BACKGROUND

The disclosure generally relates to a manufacturing method for a solid-state image pickup device, a solid-state image pickup device and an image pickup apparatus which includes a solid-state image pickup device.

In recent years, an increase of the number of pixels and refinements of a CMOS image sensor have been and are occurring.

However, as refinement of pixels proceeds, deterioration of various pixel characteristics becomes evident.

Thus, it has been proposed to carry out ion implantation into pixels in order to keep or improve a pixel characteristic such as a saturation charge amount (Qs), improvement in transfer, improvement in white point and/or improvement in sensitivity. Such a configuration is disclosed in Japanese Patent Laid-Open Nos. 2005-223134 (hereinafter referred to as Patent Document 1), 2002-373978 (hereinafter referred to as Patent Document 2) or 2004-273913 (hereinafter referred to as Patent Document 3).

By carrying out ion implantation into pixels in this manner, it is possible to add a new impurity region to the known structure to control the potential distribution and thereby improve pixel characteristics.

However, such a configuration complicates the structure of pixels because a new impurity region is additionally required.

Consequently, the number of manufacturing steps increases and gives rise to increase of the manufacturing cost. Therefore, also the cost of an image sensor chip increases.

### SUMMARY

As a configuration which improves a pixel characteristic against deterioration of the pixel characteristic caused by refinement of pixels, it is possible to use a configuration as shown in FIG. 6 which shows a schematic cross sectional view of a solid-state image pickup device.

Referring to FIG. 6, the solid-state image pickup device is configured such that pixels are separated from each other by a p-type device separation region 53, and a photodiode (PD) and a charge transfer portion of a sensor section are formed in the inside separated by the device separation region 53. Reference number 51 in FIG. 6 denotes a semiconductor substrate member which is configured from a semiconductor substrate or a semiconductor substrate and a semiconductor epitaxial layer on the semiconductor substrate. Reference number 52 denotes a p⁻ semiconductor well region formed in an embedded state in the semiconductor substrate 51.

In the solid-state image pickup device of FIG. 6, particularly at the location of the photodiode, a p⁺ region 56 having an impurity concentration lower than that of a p⁺⁺ positive charge accumulation region 58 formed on the surface of the solid-state image pickup device for suppressing dark current is formed between an n⁺ charge accumulation region 55 and the positive charge accumulation region 58. The p⁺ region 56 is formed such that it extends from the photodiode to a position below a transfer gate 60.

Although a saturation charge amount (Qs) is accumulated while the pinning by the side of the transfer gate 60 is reinforced by the positive charge accumulation region 58, the pinning below the transfer gate 60 is not sufficiently provided by the positive charge accumulation region 58. This gives rise to a problem that a white point is likely to appear. Since the p⁺ region 56 is formed so as to extend to a position below the transfer gate 60, the pinning of the transfer gate 60 can be reinforced.

However, if only the p⁺ region 56 is provided, the potential below the transfer gate 60 becomes less likely to be modulated by the p⁺ region 56, resulting in generation of a transfer barrier.

Therefore, in order to assist potential modulation when the transfer gate 60 is on, an n⁻ region 57 is provided. The n⁻ region 57 is formed such that it passes below the transfer gate 60 and extends to a position below an n-type floating diffusion 59.

By the provision of the n⁻ region 57, transfer of charge can be improved.

Further, a p⁻ region 54 of a low concentration is formed below the charge accumulation region 55 to make the overflow barrier (OFB) between the photodiode and the floating diffusion higher to increase the saturation charge amount (Qs) of the photodiode.

When this solid-state image pickup device is to be manufactured, the impurity regions are formed by ion implantation. The ion implantation steps from within the manufacturing process for the solid-state image pickup device of FIG. 6 are illustrated in FIGS. 7A to 7C. It is to be noted, however, that, in FIGS. 7A to 7C, the p-type device separation region 53 for separating the pixels is not shown.

First, an n⁻ region 57 is formed by ion implantation of an n-type impurity and a p⁺ region 56 is formed by ion implantation of a p-type impurity as seen in FIG. 7A.

Then, after a transfer gate 60 is formed, region 54 is formed by ion implantation of a p-type impurity and an n⁺ charge accumulation region 55 is formed by ion implantation of an n-type impurity using the transfer gate 60 as a mask as seen in FIG. 7B.

Then, side walls 61 are formed from an insulating layer on the opposite sides of the transfer gate 60, and an n-type floating diffusion 59 and a p⁺⁺ positive charge accumulation region 58 are successively formed using also the side walls 61 as a mask as seen in FIG. 7C.

Thereafter, a device separation region 53 is formed. By this, the solid-state image pickup device shown in FIG. 6 can be manufactured.

It is to be noted that the device separation region 53 may otherwise be formed prior to formation of the impurity regions.

Ion implantation steps which are a partly modified form of the ion implantation steps described hereinabove with reference to FIGS. 7A to 7C are illustrated in FIGS. 8A to 8C.

FIG. 8A illustrates a state that is the same as illustrated in FIG. 7A, and an n⁻ region 57 and a p⁺ region 56 are formed.

Then, a transfer gate 60 and side walls 61 on the opposite sides of the transfer gate 60 are successively formed, and a p⁻ region 54 and an n⁺ charge accumulation region 55 are formed using also the side walls 61 as a mask as seen in FIG. 8B.

Then, an n-type floating diffusion 59 and a p⁺⁺ positive charge accumulation region 58 are successively formed using also the side walls 61 as a mask as seen in FIG. 8C.

Thereafter, a device separation region 53 is formed.

In the solid-state image pickup device manufactured in this instance, the left ends of the charge accumulation region 55 and the p⁻ region 54 are displaced rightwardly by a distance provided by one of the side walls 61 from those in the configuration of FIG. 6.

In both of the ion implantation steps described hereinabove with reference to FIGS. 7A to 7C and 8A to 8C, the ranges of the four impurity regions of the p⁻ region 54, charge accumulation region 55, n⁻ region 57 and p⁺ region 56 are different from each other. Therefore, it is necessary to form a different mask for every ion implantation for forming an impurity region.

Therefore, many manufacturing steps are required, and a high manufacturing cost is required. Consequently, a high cost is required also for a chip of an image sensor.

Further, since the potential gradient below the transfer gate 60 is influenced by misalignment in ion implantation, it is necessary to strictly manage the accuracy of alignment in photolithography for forming a mask.

In order to address the problems described above, disclosed herein are one or more disclosures that provide a manufacturing method for a solid-state image pickup device and a solid-state image pickup device by which a pixel characteristic can be improved and the manufacturing cost can be reduced. The disclosure(s) further provide an image pickup apparatus which includes the solid-state image pickup device. Accordingly, disclosed herein are one or more presently preferred embodiments of a solid-state image pickup devices and methods for manufacturing the same.

In one presently preferred embodiment, the solid-state image pick up device includes a substrate, a first charge accumulation region formed within the substrate, a first impurity region formed within the substrate and located above the charge accumulation region and a gate electrode disposed on a surface of the substrate which is closer to the first impurity region. Further, in this embodiment, a portion of the first impurity region and the charge accumulation region extends underneath a portion of the gate electrode, and edges of the charge accumulation region and first impurity region which lie underneath the gate electrode are in registry with each other.

In another presently preferred embodiment, the second impurity region is located below the charge accumulation region.

In another presently preferred embodiment, a second charge accumulation region can be formed within the substrate, which is located above the first impurity region. Further, an impurity concentration of the second impurity region can be lower than an impurity concentration of the first charge accumulation region.

In another presently preferred embodiment of the solid-state image pickup device a first device separation region can be formed within the substrate, which is located underneath and to the left of the gate electrode and a second device separation region can be formed within the substrate and located underneath and to the of right of the gate electrode. In this embodiment, the second impurity region extends to an inner edge of the first separation region.

In yet another presently preferred embodiment of the solid-state image pickup device, the second impurity region can extend across the length of the substrate.

In a presently preferred embodiment for manufacturing a solid-state image pickup device, the method includes the steps of forming a first charge accumulation region above the first impurity region via ion implantation, forming a first impurity region above the charge accumulation region via ion implantation, and disposing a gate electrode on a surface of the substrate which is closer to the first impurity region. In this embodiment, a portion of the first impurity region and the charge accumulation region extend underneath a portion of the gate electrode, and edges of the charge accumulation layer and second impurity region which lie underneath the gate electrode are in registry with each other.

In another manufacturing embodiment of the solid-state image pickup device a second impurity can be formed via ion implantation below the charge accumulation region.

In another manufacturing embodiment of the solid-state image pickup device the step of forming a second charge accumulation region via ion implantation above the first impurity region can be included.

Yet further in another manufacturing method, a mask can be used in forming the first charge accumulation region, the first impurity region and the second impurity region. Further, in this embodiment, the same mask can be used to form the first charge accumulation region, the first impurity region and the second impurity region.

In another embodiment of the manufacturing method of the sold-state image pickup device an impurity concentration of the second impurity region can be formed that is lower than an impurity concentration of the charge accumulation region.

In another manufacturing embodiment the sold-state image pickup device the manufacturing methods can include forming a first device separation region underneath and to the left of the gate electrode, forming a second device separation region, underneath and to the of right of the gate electrode and forming the second impurity region so that it extends to an inner edge of the first separation region.

Further, in another manufacturing embodiment, the second impurity region can be formed so as to extend across the length of the substrate.

In another method of manufacturing a solid-state image pickup device, the method includes forming a charge accumulation region within the substrate via ion implantation, forming a first impurity region above the charge accumulation region via ion implantation, and disposing a gate electrode on a surface of the substrate which is closer to the first impurity region. Further, a portion of the first impurity region and the charge accumulation layer extend underneath a portion of the gate electrode, and the first impurity region is formed in self-alignment with the charge accumulation region at least with respect to edges of the second impurity region and the charge accumulation region extending underneath the gate electrode.

Another embodiment for the method of manufacturing the solid-state image pickup device includes forming a second impurity via ion implantation below the charge accumulation region.

In another embodiment of the disclosure, there is an apparatus that includes a solid-state image pickup device. The solid-state image pickup device further includes a substrate, a charge accumulation region formed within the substrate, a first impurity region formed within the substrate and located above the charge accumulation region and a gate electrode disposed on a surface of the substrate which is closer to the second impurity region. Further, a portion of the first impurity region and the charge accumulation region extends underneath a portion of the gate electrode, and edges of the charge accumulation region and first impurity region which lie underneath the gate electrode are in registry with each other.

### BRIEF DESCRIPTION OF THE DRAWINGS

FIG. 1 is a schematic sectional view showing a solid-state image pickup device according to principles of the present disclosure(s);

FIGS. 2A to 2C are schematic sectional views illustrating different steps of a manufacturing method according to principles of the present disclosure(s) for the solid-state image pickup device of FIG. 1;

FIG. 3 is a schematic sectional view showing a solid-state image pickup device according to principles of the present disclosure(s);

FIG. 4 is a schematic sectional view showing a solid-state image pickup device according to principles of the present disclosure(s);

FIG. 5 is a block diagram showing an image pickup apparatus according to principles of the present disclosure(s);

FIG. 6 is a schematic sectional view of a solid-state image pickup device according to principles of the present disclosure(s);

FIGS. 7A to 7C are schematic sectional views illustrating different steps of a manufacturing method according to principles of the present disclosure(s) for the solid-state image pickup device of FIG. 6; and

FIGS. 8A to 8C are schematic sectional views illustrating different steps of a modified manufacturing method according to principles of the present disclosure(s).

### DETAILED DESCRIPTION OF THE PREFERRED EMBODIMENTS

The presently preferred embodiments according to principles of the present disclosure(s) are described in detail hereinafter with reference to the accompanying drawings. Although the presently preferred embodiments will be described below with various technically preferred limitations, the scope(s) of the present disclosure(s) as set forth in the claims is/are not limited thereto unless otherwise described below.

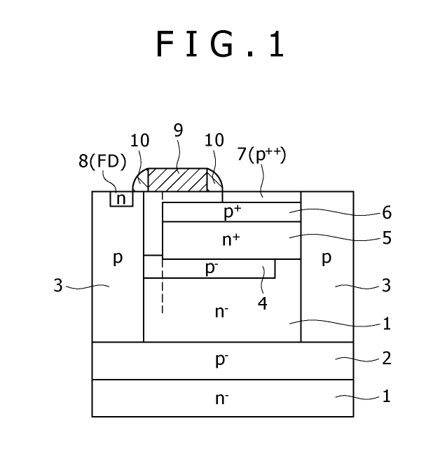

Presently preferred embodiments of the present disclosure(s) relate to a general configuration of a solid-state image pickup device shown in FIG. 1.

Referring to FIG. 1, the solid-state image pickup device shown is configured such that a photodiode (PD) of a sensor section, a charge transfer section in the form of a transfer gate 9, and a floating diffusion (FD) 8 are formed on the surface of an n⁻ semiconductor substrate 1 made of silicon or some other semiconductor.

For the semiconductor substrate 1, a semiconductor substrate such as a silicon substrate or a semiconductor substrate and a semiconductor epitaxial layer on the semiconductor substrate can be used.

The semiconductor substrate 1 has a p⁻ semiconductor well region 2 formed in an embedded state therein.

The semiconductor well region 2 is formed over an overall area of a pixel region or over an overall area of a chip of the solid-state image pickup device and separates the substrate and the pixel section from each other.

Above the semiconductor well region 2, pixels are separated from each other by a p-type device separation region 3. In the inside separated by the device separation region 3, a photodiode (PD) of the sensor section and the charge transfer section are formed.

Around the photodiode, a p⁺ region 6 having an impurity concentration lower than that of a p⁺⁺ positive charge accumulation region 7 for dark current suppression formed on the surface of the solid-state image pickup device is provided between an n⁺ charge accumulation region 5 and the positive charge accumulation region 7.

Further, a p⁻ region 4 of a low concentration is formed below the charge accumulation region 5. Preferably, the impurity concentration of the p⁻ region 4 is lower than that of the charge accumulation region 5 in order to assure a high saturation charge amount (Qs).

In the charge transfer section, the transfer gate 9 is formed on the surface of the semiconductor substrate 1 with a thin gate insulating film not shown interposed therebetween. Side walls 10 are formed from an insulating layer on opposite sides of the transfer gate 9.

The transfer gate 9 can be formed, for example, from polycrystalline silicon.

The n-type floating diffusion (FD) 8 is formed on the surface of the device separation region 3 on the left in FIG. 1.

The floating diffusion 8 and the positive charge accumulation region 7 of the sensor section are formed on the outer sides of the side walls 10 of the transfer gate 9 with respect to the positions of the side walls 10.

The transfer gate 9 plays a role of transferring charge between the photodiode and the floating diffusion 8. The floating diffusion 8 accumulates charge transferred thereto.

The impurity concentration of the impurity regions is set such that, for example, it is of the order of 10¹⁰ cm⁻³ in the semiconductor well region 2, of the order of 10¹² cm⁻³ in the device separation region 3 and approximately 10¹¹ to 10¹² cm⁻³ in the p⁻ region 4.

In this presently preferred embodiment, particularly the charge accumulation region 5 and the p⁺ region 6 on the charge accumulation region 5 are formed in a self-aligned state. Further, the charge accumulation region 5 and the p⁺ region 6 are formed such that left end edges thereof are aligned with each other as indicated by broken lines in FIG. 1.

Further, both of the charge accumulation region 5 and the p⁺ region 6 are formed so as to extend to a position below the transfer gate 9.

Since the p⁺ region 6 is formed so as to extend to the position below the transfer gate 9, the pinning below the transfer gate 9 can be reinforced similarly to the configuration described hereinabove with reference to FIG. 6.

Since the n⁺ charge accumulation region 5 is formed so as to extend to the position below the transfer gate 9, generation of a transfer barrier by the p⁺ region 6 can be prevented and thereby improve transfer of charge. Consequently, even if the n⁻ region 57 illustrated in FIG. 6 is not provided, since the charge accumulation region 5 can achieve the same role as that of the n⁻ region 57, it is possible to decrease the region into which ion implantation is to be carried out and decrease the number of man-hours.

Then, since the charge accumulation region 5 and the p⁺ region 6 on the charge accumulation region 5 are formed in a self-aligned state, the same mask can be used to carry out ion implantation successively into the charge accumulation region 5 and the p⁺ region 6. Consequently, the number of masks can be reduced.

Further, in this presently preferred embodiment, the p⁻ region 4 below the charge accumulation region 5 is formed so as to extend from the sensor section to the device separation region 3 on the left side through a position below the transfer gate 9.

By the p⁻ region 4, the overflow barrier (OFB) between the photodiode and the floating diffusion can be made higher thereby to increase the saturation charge amount (Qs) of the photodiode. Further, since the p⁻ region 4 is also formed below the transfer gate 9, the overflow barrier can be made higher than that in the configuration described hereinabove with reference to FIG. 6.

The solid-state image pickup device of the present embodiment can be manufactured in such a manner as described below.

It is to be noted that, since steps other than ion implantation steps can be carried out for the solid-state image pickup device of the presently preferred embodiment in a similar manner as in the case of the known solid-state image pickup device, a detailed description of these common steps is omitted herein.

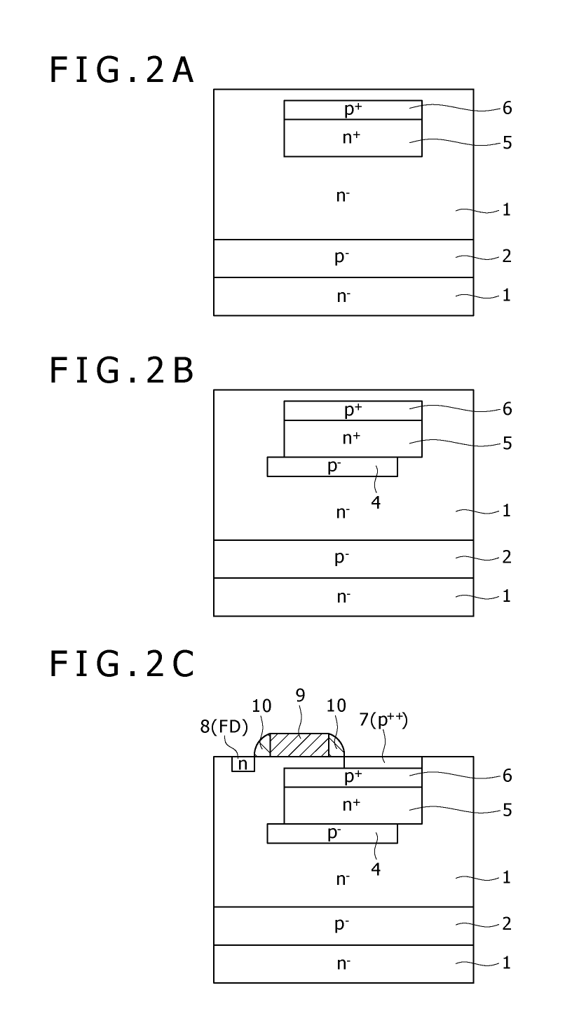

First, an n⁺ charge accumulation region 5 is formed by ion implantation of an n-type impurity and a p⁺ region 6 is formed by ion implantation of a p-type impurity using the same mask as seen in FIG. 2A.

Consequently, the charge accumulation region 5 and the p⁺ region 6 are formed in a self-aligned state.

Although the n⁺ region and the p⁺ region overlap with each other immediately after the ion implantation, if the impurities are diffused by heat for activating the impurities, then some displacement or misalignment sometimes occurs between end edges of the charge accumulation region 5 and the p⁺ region 6. It is possible to suppress the displacement so as to fall within a range of several tens nm.

Then, a p⁻ region 4 is formed by ion implantation of a p-type impurity using another mask as seen in FIG. 2B. Here, preferably the dose amount of the p-type impurity into the p⁻ region 4 is set smaller than the dose amount of the n-type impurity of the charge accumulation region 5 so that the impurity concentration of the p⁻ region 4 may be lower than the impurity concentration of the charge accumulation region 5.

Thereafter, a transfer gate 9 and side walls 10 on the opposite sides of the transfer gate 9 are successively formed as seen in FIG. 2C, and an n-type floating diffusion 8 and a p⁺⁺ positive charge accumulation region 7 are successively formed using also the side walls 10 as a mask. It is to be noted that the transfer gate 9 is formed so as to extend to a position above the charge accumulation region 5 and the p⁺ region 6. Consequently, the charge accumulation region 5 and the p⁺ region 6 are formed so as to extend to a position below the transfer gate 9.

Thereafter, the device separation region 3 is formed. Consequently, the solid-state image pickup device shown in FIG. 1 can be manufactured.

It is to be noted that the device separation region 3 can be formed otherwise before formation of the impurity regions 4, 5, 6, 7 and 8 described hereinabove.

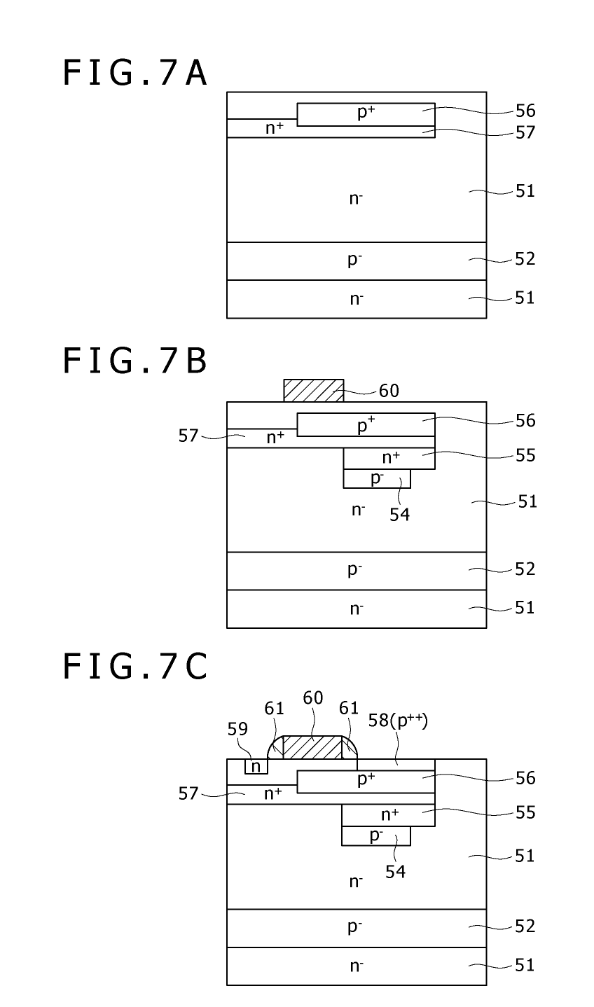

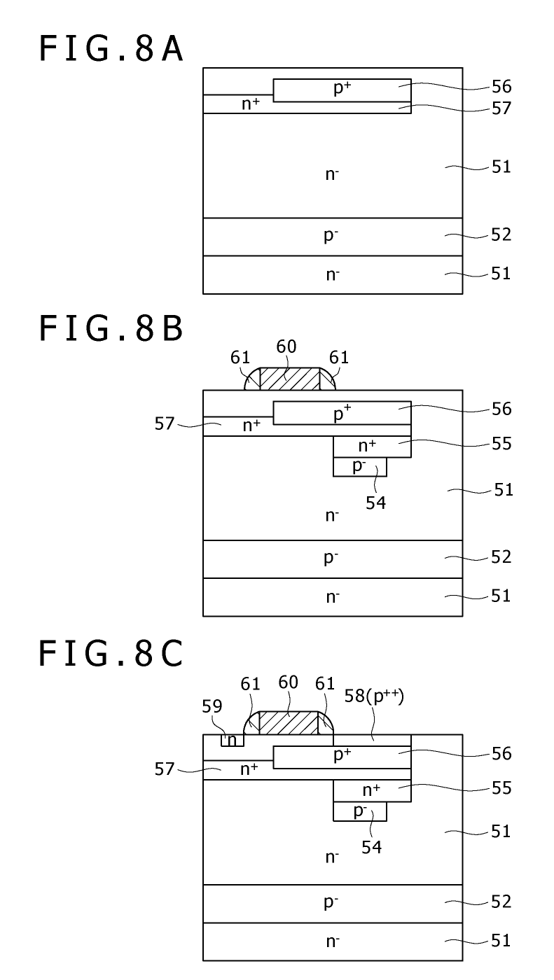

If the manufacturing process described above is compared with the manufacturing process of the solid-state image pickup device shown in FIG. 6 described with reference to FIGS. 7A to 7C, then the former is different from the latter in that, in the manufacturing process, from among the three times of ion implantation before the formation of the transfer gate 9, two of the ion implantations are carried out using the same mask. Since two of the ion implantations are carried out using the same mask, it is possible to reduce the number of masks and reduce the number of steps. Further, the margin against misalignment can be increased.

With the configuration of the presently preferred embodiment described above, since the charge accumulation region 5 and the p⁺ region 6 on the charge accumulation region 5 are formed in a self-aligned state, they can be formed individually by ion implantation using the same mask. Consequently, the number of masks to be used to manufacture a solid-state image pickup device can be reduced to reduce the number of steps. Further, the margin against misalignment can be increased.

Accordingly, the manufacturing cost can be reduced and reduction in required time and improvement in yield can be anticipated.

Further, the charge accumulation region 5 and the p⁺ region 6 are formed so as to extend to a position below the transfer gate 9.

Since the p⁺ region 6 is formed so as to extend to a position below the transfer gate 9, the pinning below the transfer gate 9 can be reinforced.

Further, since the n⁺ charge accumulation region 5 is formed so as to extend to the position below a transfer gate 9, the charge accumulation region 5 itself is modulated. Further, since generation of a transfer barrier is suppressed by the p⁺ region 6, transfer of charge can be improved. Consequently, when compared with the solid-state image pickup device of FIG. 6, since the charge accumulation region 5 can play a role same as that of the n⁻ region 57 shown in FIG. 6, the n⁻ region 57 becomes unnecessary.

Accordingly, the number of regions into which ion implantation is to be carried out can be reduced, and also in this regard, the number of steps can be reduced.

Further, the p⁻ region 4 below the charge accumulation region 5 is formed so as to extend to the device separation region 3 on the left past a position below the transfer gate 9. Consequently, the overflow barrier between the photodiode and the loading diffusion can be raised by the p⁻ region 4 thereby to increase the saturation charge amount (Qs) of the photodiode. Furthermore, the overflow barrier can be made higher than that of the solid-state image pickup device of FIG. 6.

Further, together with the fact that the charge accumulation region 5 itself is modulated, transfer can be carried out well even if the gate length of the transfer gate 9 is reduced by action of the p⁻ region 4. Consequently, also it is possible to reduce the gate length of the transfer gate 9 thereby to reduce the pixel size.

Incidentally, in FIG. 1, only a photodiode of one pixel and one floating diffusion are shown.

In the presently preferred embodiment, it is also possible to further use a configuration whereon one floating diffusion (FD) is shared by a plurality of, for example, two or four or more, pixels.

If a floating diffusion is shared by a plurality of pixels, then since, different from the configuration wherein a floating diffusion is not shared, the positional relationship between the floating diffusion and a pixel is not equal among all pixels, the position of the floating diffusion as viewed from the photodiode (PD) is different among the plural pixels which share a floating diffusion.

Therefore, if misalignment between the floating diffusion, which is formed with reference to the transfer gate, and the charge accumulating region of the photodiode occurs, then the distance between the floating diffusion and the photodiode becomes different among the plural pixels which share the floating diffusion. At this time, a difference appears in a pixel characteristic such as the saturation current amount (Qs) among the pixels.

In the present embodiment, since the p⁻ region 4 is formed below the charge accumulation region 5, even if the configuration wherein the floating diffusion 8 (FD) is shared by a plurality of pixels is adopted, the difference of a pixel characteristic such as the saturation current amount (Qs) can be reduced by an action of the p⁻ region 4.

Further, in the present embodiment, since the p⁻ region 4 is formed in a displaced relationship from the charge accumulation region 5 toward the floating diffusion 8 side, that is, toward the transfer gate 9 side, the difference of a pixel characteristic such as the saturation current amount (Qs) can be further reduced.

It is to be noted that, while, in the embodiment described above, the p⁻ region 4 is formed using a mask different from that used for the charge accumulation region 5 and the p⁺ region 6, also it is possible to use the same mask to form the p⁻ region 4 by ion implantation.

In this instance, the p⁻ region 4 is formed in a self-aligned state with the charge accumulation region 5 and the p⁺ region 6 and formed so as to extend to an intermediate position below the transfer gate 9 similarly to the charge accumulation region 5 and the p⁺ region 6.

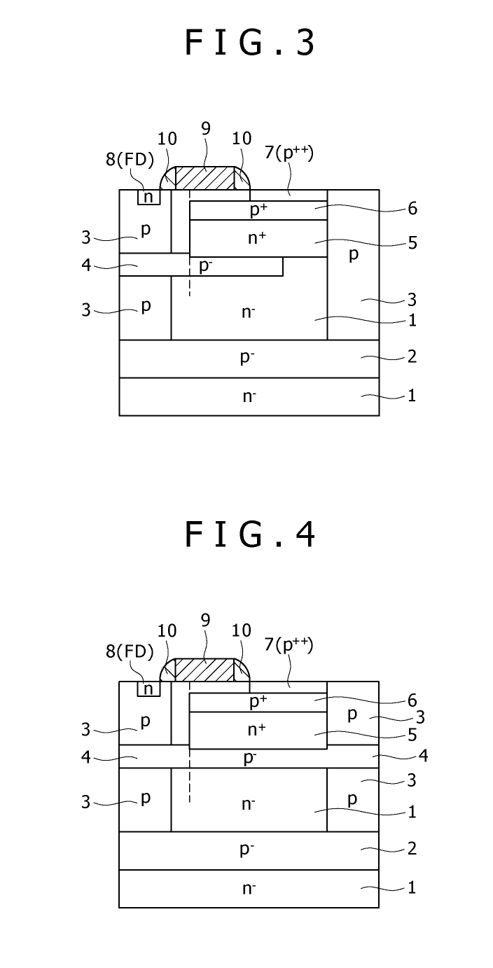

A general configuration of a solid-state image pickup device according to another presently preferred embodiment of the present disclosure(s) is shown in FIG. 3.

The solid-state image pickup device according to this presently preferred embodiment is similar in configuration to the solid-state image pickup device described hereinabove with reference to FIGS. 1 and 2A to 2C. As such, a description of the common configuration is omitted herein to avoid redundancy.

The solid-state image pickup device of the present embodiment is different from the solid-state image pickup device of the first embodiment in that the p⁻ region 4 formed below the charge accumulation region 5 is formed so as to extend to a position below the floating diffusion 8.

The solid-state image pickup device of the present embodiment can be manufactured similarly to the solid-state image pickup device of the first embodiment if the pattern of the mask to be used for the ion implantation step for forming the p⁻ region 4 is changed.

With the configuration of the solid-state image pickup device of the present embodiment described above, the charge accumulation region 5 and the p⁺ region 6 on the charge accumulation region 5 are formed in a self-aligned state and extend to a position below the transfer gate 9 similarly as described with reference to FIGS. 1 and 2A-2C.

Consequently, the number of masks to be used to manufacture the solid-state image pickup device can be reduced and the number of steps can be reduced. Further, the margin against misalignment can be increased.

Accordingly, the manufacturing cost can be reduced, and reduction in required time and improvement in yield can be anticipated.

Further, the pinning below the transfer gate 9 can be reinforced and transfer of charge can be improved, and consequently, the n⁻ region 57 shown in FIG. 6 becomes unnecessary.

Accordingly, the number of regions into which ion implantation is to be carried out can be reduced, and also in this regard, the number of steps can be reduced.

Further, the p⁻ region 4 below the charge accumulation region 5 is formed so as to extend to a position below the floating diffusion 8 in the device separation region 3 on the left past a position below the transfer gate 9.

Consequently, the overflow barrier between the photodiode and the loading diffusion can be raised by the p⁻ region 4 thereby to increase the saturation charge amount (Qs) of the photodiode. Furthermore, the overflow barrier can be made higher than that of the solid-state image pickup device of FIG. 6.

Further, together with the fact that the charge accumulation region 5 itself is modulated, transfer can be carried out well even if the gate length of the transfer gate 9 by action of the p⁻ region 4. Consequently, also it is possible to reduce the gate length of the transfer gate 9 thereby to reduce the pixel size.

Also in the presently preferred embodiment, it is possible to further use a configuration whereon one floating diffusion (FD) is shared by a plurality of, for example, two or four or more pixels.

In the presently preferred embodiment, since the p⁻ region 4 is formed below the charge accumulation region 5, even if the configuration wherein one floating diffusion (FD) 8 is shared by a plurality of pixels is adopted, the difference of a pixel characteristic such as the saturation current amount (Qs) can be reduced by an action of the p⁻ region 4.

Furthermore, in the presently preferred embodiment, since the p⁻ region 4 is formed so as to extend to a position below the floating diffusion 8, the difference of a pixel characteristic such as the saturation current amount (Qs) among the pixels can be reduced, and the difference of a pixel characteristic can be reduced further from that in the preferred embodiment described with respect to FIGS. 1 and 2A-2C.

A general configuration of a solid-state image pickup device according to another presently preferred embodiment of the present disclosure(s) is shown in FIG. 4.

The solid-state image pickup device according to the present embodiment is similar in configuration to the solid-state image pickup devices of the previously described presently preferred embodiments described hereinabove with reference to FIGS. 1 and 2A to 2C and FIG. 3, respectively, and overlapping description of the common configuration is omitted herein to avoid redundancy.

The solid-state image pickup device of this presently preferred embodiment is different from the solid-state image pickup devices described hereinabove with reference to FIGS. 1 and 2A to 2C and FIG. 3, in that the p⁻ region 4 formed below the charge accumulation region 5 is formed over the overall area of the pixel through the device separation region 3 formed leftwardly and rightwardly.

Preferably, the p⁻ region 4 is formed over the overall area of the pixel region or over the overall area of the chip of the solid-state image pickup device similarly to the semiconductor well region 2.

The solid-state image pickup device of this presently preferred embodiment can be manufactured similarly to the solid-state image pickup device of the first embodiment if the pattern of the mask to be used for the ion implantation step for forming the p⁻ region 4 is changed.

With the configuration of the solid-state image pickup device of the present embodiment described above, the charge accumulation region 5 and the p⁺ region 6 on the charge accumulation region 5 are formed in a self-aligned state and extend to a position below the transfer gate 9 similarly as in presently preferred embodiment described with reference to FIGS. 1 and 2A-2C.

Consequently, similar to this embodiment, the number of masks to be used to manufacture the solid-state image pickup device can be reduced and the number of steps can be reduced. Further, the margin against misalignment can be increased.

Accordingly, the manufacturing cost can be reduced, and reduction in required time and improvement in yield can be anticipated.

Further, the pinning below the transfer gate 9 can be reinforced and transfer of charge can be improved, and consequently, the n⁻ region 57 shown in FIG. 6 becomes unnecessary.

Accordingly, the number of regions into which ion implantation is to be carried out can be reduced, and also in this regard, the number of steps can be reduced.

Further, the p⁻ region 4 below the charge accumulation region 5 is formed also below the transfer gate 9 and below the floating diffusion 8 in the device separation region 3 on the left.

Consequently, the overflow barrier between the photodiode and the loading diffusion can be raised by the p⁻ region 4 thereby to increase the saturation charge amount (Qs) of the photodiode. Furthermore, the overflow barrier can be made higher than that of the solid-state image pickup device of FIG. 6.

Further, together with the fact that the charge accumulation region 5 itself is modulated, transfer can be carried out well even if the gate length of the transfer gate 9 by action of the p⁻ region 4. Consequently, also it is possible to reduce the gate length of the transfer gate 9 thereby to reduce the pixel size.

Further, in this presently preferred embodiment, since the p⁻ region 4 is formed over the overall area of the pixel, misalignment between the p⁻ region 4 and the other impurity regions 5, 6 and 7 does not occur at all. Consequently, deterioration of the yield in manufacture caused by misalignment between the p⁻ region 4 and the other impurity regions 5, 6 and 7 can be prevented.

Also in this presently preferred embodiment, it is possible to further use a configuration whereon one floating diffusion (FD) is shared by a plurality of, for example, two or four or more pixels.

In this presently preferred embodiment, since the region 4 is formed below the charge accumulation region 5, even if the configuration wherein one floating diffusion (FD) 8 is shared by a plurality of pixels is adopted, the difference of a pixel characteristic such as the saturation current amount (Qs) can be reduced by an action of the p⁻ region 4.

Furthermore, in this presently preferred embodiment, since the p⁻ region 4 is formed so as to extend to a position below the floating diffusion 8, the difference of a pixel characteristic such as the saturation current amount (Qs) among the pixels can be reduced, and the difference of a pixel characteristic can be reduced further from that in the first embodiment.

It is to be noted that, in the presently preferred embodiments described hereinabove, the conduction type of the charge accumulation region 5 of the first conduction type of the photodiode of the sensor section is the n type while the conduction type of the impurity region of the second conduction type on the charge accumulation region 5, that is, of the p⁺ region 6 and the positive charge accumulation region 7, is the p type.

In an embodiment of the present disclosure(s), also it is possible to reverse the conduction types from those in the embodiments described hereinabove such that a solid-state image pickup device includes a p-type charge accumulation region and an n-type impurity region such as an n⁺ region or a negative charge accumulation region formed on the p-type charge accumulation region.

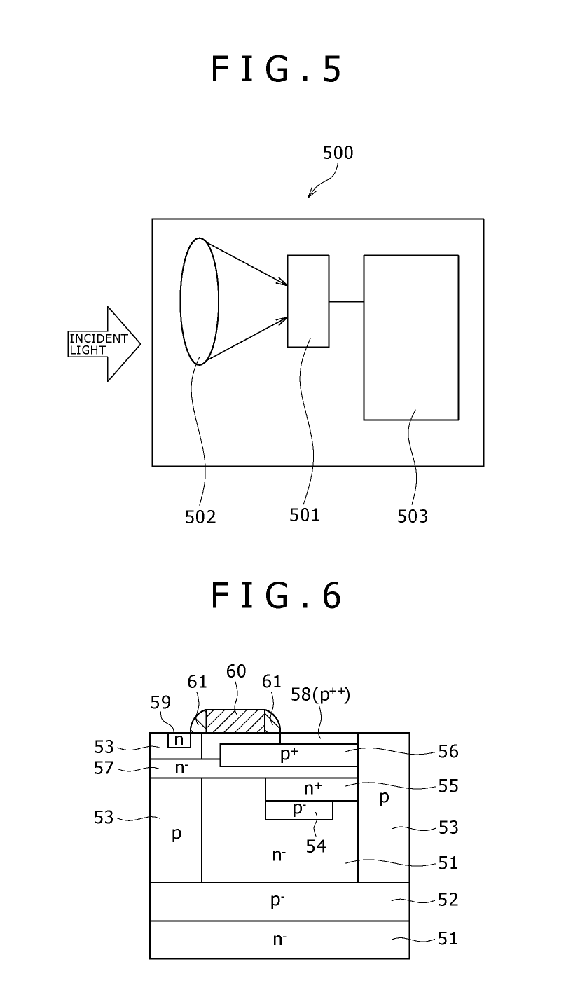

A general configuration of an image pickup apparatus according to another presently preferred embodiment of the disclosure(s) is shown in FIG. 5.

The image pickup apparatus may be, for example, a video camera, a digital still camera or a camera of a portable telephone set.

Referring to FIG. 5, the image pickup apparatus 500 shown includes an image pickup section 501 including a solid-state image pickup device not shown. The image pickup apparatus 500 further includes an image forming optical system 502 provided at a preceding stage to the image pickup section 501 for condensing incident light to form an image. The image pickup apparatus 500 further includes a signal processing section 503 provided at a succeeding stage to the image pickup section 501 and including a driving circuit for driving the image pickup section 501, a signal processing circuit for processing a signal obtained by photoelectric conversion by the solid-state image pickup device into an image, and so forth. The image signal obtained by the processing by the signal processing section 503 can be stored into an image storage section not shown.

The solid-state image pickup device of the present disclosure such as the solid-state image pickup devices of the presently preferred embodiments described hereinabove can be used as the solid-state image pickup device in such an image pickup apparatus 500 as described above.

With the image pickup apparatus 500 of the above described presently preferred embodiment, the solid-state image pickup device of the present disclosure(s), that is, a solid-state image pickup device with which the manufacturing cost can be reduced and reduction of the required time and improvement of the yield can be anticipated, is used. Consequently, the image pickup apparatus 500 is advantageous in that it can be configured at a reduced cost and operates stably with high reliability.

It is to be noted that the image pickup apparatus of the present disclosure(s) is not limited to that having the configuration described above with reference to FIG. 5, and the present disclosure can be applied to any image pickup apparatus which uses the solid-state image pickup device.

For example, the solid-state image pickup device may have a form as a one-chip solid-state image pickup device or have a form of a module wherein the image pickup section and the signal processing section or the optical system are packaged collectively such that it has an image pickup function.

The image pickup apparatus of the present disclosure(s) may be applied to various image pickup apparatus such as, for example, a camera or a portable apparatus having an image pickup function. Further, the term “image pickup” is herein used to signify such a broad sense as to include a fingerprint detection apparatus and so forth.

While the presently preferred embodiments of the disclosure(s) have been described using specific terms, such description is for illustrative purpose only, and it is to be understood that changes and variations may be made without departing from the spirit or scope of the following claims.

It should be understood by those skilled in the art that various modifications, combinations, sub-combinations and alterations may occur depending on design requirements and other factor in so far as they are within the scope of the appended claims or the equivalents thereof.

What is claimed is:

1. A solid-state image pickup device comprising:
a substrate;
a first charge accumulation region formed within the substrate;
a first impurity region formed within the substrate and located above the charge accumulation region; and
a gate electrode disposed on a surface of the substrate which is closer to the first impurity region, wherein,
a portion of the first impurity region and the charge accumulation region extends underneath a portion of the gate electrode, and
edges of the charge accumulation region and first impurity region which lie underneath the gate electrode are in registry with each other.

2. The solid-state image pickup device according to claim 1, wherein a second impurity region is located below the charge accumulation region.

3. The solid-state image pickup device according to claim 1, wherein a second charge accumulation region is formed within the substrate and located above the first impurity region.

4. The solid-state image pickup device according to claim 2 wherein an impurity concentration of the second impurity region is lower than an impurity concentration of the first charge accumulation region.

5. The solid-state image pickup device according to claim 2 further comprising:
a first device separation region formed within the substrate and located underneath and to the left of the gate electrode; and
a second device separation region, formed within the substrate and located underneath and to the of right of the gate electrode, wherein, the second impurity region extends to an inner edge of the first separation region.

6. The solid-state image pickup device according to claim 2, wherein the second impurity region extends across the length of the substrate.

7. A method of manufacturing a solid-state image pickup device comprising:
forming a first charge accumulation region above the first impurity region via ion implantation;
forming a first impurity region above the charge accumulation region via ion implantation; and
disposing a gate electrode on a surface of the substrate which is closer to the first impurity region, wherein,
a portion of the first impurity region and the charge accumulation region extend underneath a portion of the gate electrode, and
edges of the charge accumulation layer and second impurity region which lie underneath the gate electrode are in registry with each other.

8. The method of manufacturing the solid-state image pickup device according to claim 7, further comprising forming a second impurity via ion implantation below the charge accumulation region

9. The method of manufacturing the solid-state image pickup device according to claim 7 further comprising forming a second charge accumulation region via ion implantation above the first impurity region.

10. The method of manufacturing the sold-state image pickup device according to claim 9, wherein a mask is used in the step of forming the first charge accumulation region, the first impurity region and the second impurity region.

11. The method of manufacturing the sold-state image pickup device according to claim 10, wherein the same mask is used in the step of forming the first charge accumulation region, the first impurity region and the second impurity region.

12. The method of manufacturing the sold-state image pickup device according to claim 8 wherein an impurity concentration of the second impurity region is lower than an impurity concentration of the charge accumulation region.

13. The method of manufacturing the sold-state image pickup device according to claim 8 further comprising:
forming a first device separation region underneath and to the left of the gate electrode;
forming a second device separation region, underneath and to the of right of the gate electrode; and
forming the second impurity region so that it extends to an inner edge of the first separation region.

14. The method of manufacturing the sold-state image pickup device according to claim 8 wherein the second impurity region extends across the length of the substrate.

15. A method of manufacturing a solid-state image pickup device comprising:
forming a charge accumulation region within the substrate
via ion implantation;
forming a first impurity region above the charge accumulation region via ion implantation; and
disposing a gate electrode on a surface of the substrate which is closer to the first impurity region, wherein,
a portion of the first impurity region and the charge accumulation layer extend underneath a portion of the gate electrode, and
the first impurity region is formed in self-alignment with the charge accumulation region at least with respect to edges of the second impurity region and the charge accumulation region extending underneath the gate electrode.

16. The method of manufacturing the solid-state image pickup device according to claim 3, further comprising forming a second impurity via ion implantation below the charge accumulation region.

17. An apparatus comprising a solid-state image pickup device, the solid-state image pickup device comprising:
a substrate;
a charge accumulation region formed within the substrate;
a first impurity region formed within the substrate and located above the charge accumulation region; and
a gate electrode disposed on a surface of the substrate which is closer to the second impurity region, wherein,
a portion of the first impurity region and the charge accumulation region extends underneath a portion of the gate electrode, and
edges of the charge accumulation region and first impurity region which lie underneath the gate electrode are in registry with each other.

18. The solid-state image pickup device according to claim 17, wherein a second impurity region is located below the charge accumulation region.
